(19) United States
(12) Patent Application Publication
(10) Pub. No.: US 2019/0103397 A1
(43) Pub. Date: Apr. 4, 2019

(54) PROTECTING CIRCUIT

(71) Applicant: PIXART IMAGING INC., HSIN-CHU (TW)

(72) Inventors: CHIA-SO CHUANG, HSIN-CHU (TW); KUEI-JU CHIANG, HSIN-CHU (TW)

(21) Appl. No.: 15/722,014

(22) Filed: Oct. 2, 2017

(51) Int. Cl. H01L 27/02; H01L 29/772

(52) U.S. Cl. CPC H01L 27/0266; H01L 29/772

(57) ABSTRACT

A protecting circuit provided includes an ESD transistor having a source electrode, a gate electrode, and a drain electrode; and an auxiliary circuit electrically connected to the ESD transistor. When a power supply is electrically connected to the protecting circuit in correct priority, the auxiliary circuit and the ESD transistor are turned on. When the power supply is electrically connected to the protecting circuit in reverse priority, the auxiliary circuit is turned on so as to turn off the ESD transistor.

### FIELD OF THE INVENTION

The present disclosure relates to a protecting circuit, and more particularly to a protecting circuit turning off an ESD transistor when a negative voltage is applied.

### BACKGROUND OF THE INVENTION

There have been several schemes to implement a protecting circuit in the existing technology. Please refer to FIG. 1, which shows a GRNMOS structure of a protecting circuit according to a prior art, the protecting circuit includes an ESD transistor M0 and a resistor R0. When a power supply supplies a positive voltage VBAT, such as 4V, the ESD transistor M0 will be turned off, and when a power supply supplies a negative voltage VBAT, such as −4V, the ESD transistor M0 will be fully turned on to protect the circuit.

Please refer to FIG. 2, which shows a RC-INVNMOS structure of a protecting circuit according to a prior art, the protecting circuit includes an ESD transistor M0, a resistor R1, a capacitor C1, a transistor MP1, and a transistor MN1. When a power supply supplies a positive voltage VBAT, such as 4V, the ESD transistor M0 will be turned off, and when a power supply supplies a negative voltage VBAT, such as −4V, the ESD transistor M0 will be half on by parasitic diodes of the transistors MP1 and MN1 to protect the circuit.

However, the ESD transistor M0 may be used only once to protect the circuit under the negative voltage, and thus it is important to prolong the lifetime of the protecting circuit.

### SUMMARY OF THE INVENTION

One aspect of the present disclosure relates to a protecting circuit turning off an ESD transistor when a negative voltage is applied.

One of the embodiments of the present disclosure provides a protecting circuit including: an ESD transistor having a source electrode, a gate electrode, and a drain electrode; a protecting transistor having a gate electrode, a source electrode, and a drain electrode electrically connected to the gate electrode of the ESD transistor; a capacitor having a first electrode electrically connected to the gate electrode of the protecting transistor, and a second electrode electrically connected to the source electrode of the protecting transistor; and a first resistor having a first electrode electrically connected to the drain electrode of the protecting transistor. A power supply is electrically connected to the protecting circuit. The protecting transistor is configured to hold a voltage applied on the gate of the ESD transistor to ensure the ESD transistor being in an off-state when the power supply supplies a negative voltage to the protecting transistor.

Another one of the embodiments of the present disclosure provides a protecting circuit including: an ESD transistor having a source electrode, a gate electrode, and a drain electrode; a protecting transistor having a gate electrode, a source electrode, and a drain electrode electrically connected to the gate electrode of the ESD transistor; a capacitor having a first electrode electrically connected to the gate electrode of the protecting transistor, and a second electrode electrically connected to the source electrode of the protecting transistor; a first resistor having a first electrode electrically connected to the drain electrode of the protecting transistor; and a second resistor having a first electrode electrically connected to the capacitor. A power supply is electrically connected to the protecting circuit. The protecting transistor is configured to hold a voltage applied on the gate of the ESD transistor to ensure the ESD transistor being in an off-state when the power supply supplies a negative voltage to the protecting transistor.

Yet another one of the embodiments of the present disclosure provides a protecting circuit including: an ESD transistor having a source electrode, a gate electrode, and a drain electrode; and an auxiliary circuit electrically connected to the ESD transistor. When a power supply is electrically connected to the protecting circuit in correct priority, the auxiliary circuit and the ESD transistor are turned on. When the power supply is electrically connected to the protecting circuit in reverse priority, the auxiliary circuit is turned on so as to turn off the ESD transistor.

Therefore, the protecting transistor added to the present disclosure may further protect the circuit together with the ESD transistor, and prolong the lifetime of the protecting circuit.

To further understand the techniques, means and effects of the present disclosure, the following detailed descriptions and appended drawings are hereby referred to, such that, and through which, the purposes, features and aspects of the present disclosure can be thoroughly and concretely appreciated. However, the appended drawings are provided solely for reference and illustration, without any intention to limit the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 shows a circuit diagram of a protecting circuit with a GRNMOS structure according to a prior art;

FIG. 2 shows a protecting circuit with a RC-INVNMOS structure according to a prior art;

FIG. 3 shows a circuit diagram of a protecting circuit according to an embodiment of the present disclosure; and

FIG. 4 shows a sectional view of the protecting circuit in FIG. 3.

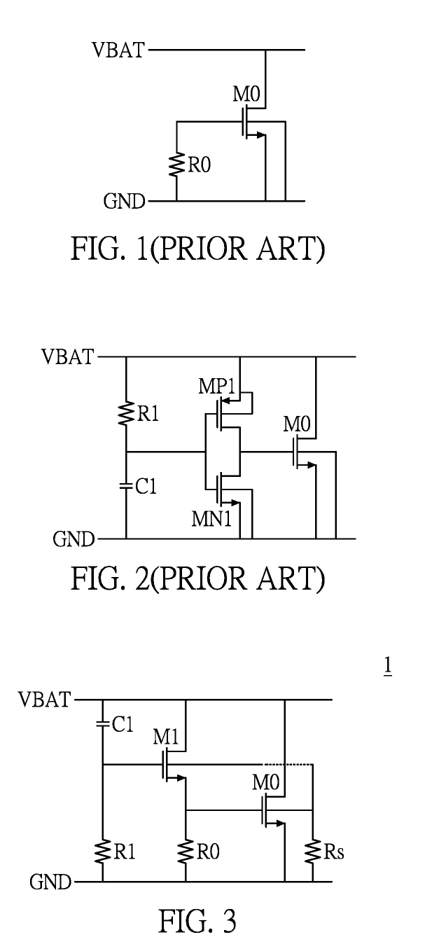

### DETAILED DESCRIPTION OF THE PREFERRED EMBODIMENTS

Embodiments of a protecting circuit according to the present disclosure are described herein. Other advantages and objectives of the present disclosure can be easily understood by one skilled in the art from the disclosure. The present disclosure can be applied in different embodiments. Various modifications and variations can be made to various details in the description for different applications without departing from the scope of the present disclosure. The drawings of the present disclosure are provided only for simple illustrations, but are not drawn to scale and do not reflect the actual relative dimensions. The following embodiments are provided to describe in detail the concept of the present disclosure, and are not intended to limit the scope thereof in any way.

Reference is made to FIG. 3, which shows a circuit diagram of a protecting circuit according to an embodiment of the present disclosure. As shown in FIG. 3, a protecting circuit 1 includes an ESD transistor M0 having a source electrode, a gate electrode, and a drain electrode; a protecting transistor M1 having a gate electrode, a source electrode, and a drain electrode electrically connected to the gate electrode of the ESD transistor M0; a capacitor C1 having a first electrode electrically connected to the gate electrode of the protecting transistor M1, and a second electrode electrically connected to the source electrode of the protecting transistor M1; a first resistor R0 having a first electrode electrically connected to the drain electrode of the protecting transistor M1; and a second resistor R1 having a first electrode electrically connected to the capacitor C1. It needs to be noted that in other embodiments, the capacitor C1 may be removed, or both the capacitor C1 and the second resistor R1 may be removed. The protecting circuit 1 in the embodiment may further include a third resistor Rs having a first electrode electrically connected to the gate of the ESD transistor M0, and a second electrode receiving a ground voltage GND. A power supply BAT is electrically connected to the protecting circuit 1, and the protecting transistor M1 is configured to hold a voltage Vg applied on the gate of the ESD transistor M0 to ensure the ESD transistor M0 being in an off-state when the power supply BAT supplies a negative voltage VBAT, such as −4V, to the protecting transistor M1. The ESD transistor M0 should be in the off-state under such circumstances because the ESD transistor M0, generally used for electrostatic protection, with the power supply BAT in reverse priority will suffer from damage.

In the embodiment, when the power supply BAT is electrically connected to the protecting circuit M1 in correct priority, the ESD transistor M0 and the protecting transistor M1 are turned off, and when the power supply BAT is electrically connected to the protecting circuit M1 in reverse priority, the ESD transistor M0 is turned off and the protecting transistor M1 is turned on. For example, if VBAT is 4V, the protecting circuit M1 will be turned off, and the ESD transistor M0 will also be turned off; if VBAT is −4V, the protecting transistor M1 will be turned on, and the ESD transistor M0 will be turned off.

It should be noted that, the ESD transistor M0 is turned on for a negative ESD stress duration before the ESD transistor M0 is turned off. That is, the second resistor R1 combined with the capacitor C1 turns on the ESD transistor M0 against the negative ESD stress for a period of time. In the embodiment, when VBAT is 4V, the protecting circuit M1 is initially turned on for a short time and then immediately turned off, while the ESD transistor M0 is also initially turned on for a short time, that is, the negative ESD stress duration, and then immediately turned off; when VBAT is −4V, the protecting transistor M1 is initially turned off for a short time and then immediately turned on, while the ESD transistor M0 is also initially turned on in the negative ESD stress duration and then immediately turned off.

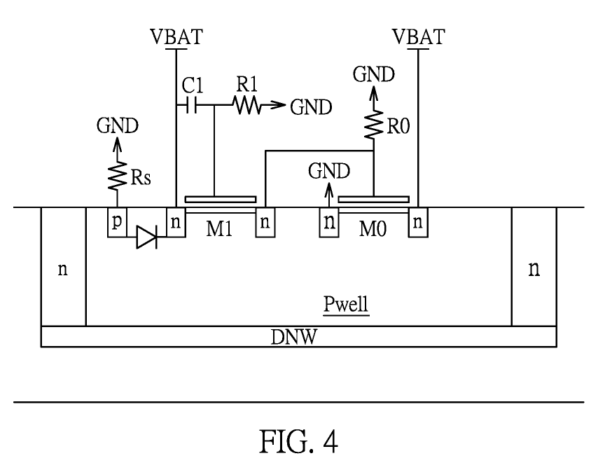

Reference is made to FIG. 4, which shows a sectional view of the protecting circuit in FIG. 3. As shown in FIG. 4, the voltage VBAT and the ground voltage GND are denoted by two marks, and it can be seen that a PN diode D is formed between the third resistor Rs and the ESD transistor M0, and there are N well areas n and P well areas p arranged on a substrate DNW.

Therefore, the protecting transistor added to the present disclosure may further protect the circuit together with the ESD transistor and prolong the lifetime of the protecting circuit.

The aforementioned descriptions merely represent the preferred embodiments of the present disclosure, without any intention to limit the scope of the present disclosure which is fully described only within the following claims. Various equivalent changes, alterations or modifications based on the claims of the present disclosure are all, consequently, viewed as being embraced by the scope of the present disclosure.

1. A protecting circuit comprising:
an electrostatic discharge (ESD) transistor (M0) having a source electrode, a gate electrode, and a drain electrode;
a protecting transistor (M1) having a gate electrode, a drain electrode, and a source electrode electrically connected to the gate electrode of the ESD transistor;
a capacitor (C1) having a first electrode electrically connected to the gate electrode of the protecting transistor, and a second electrode electrically connected to the drain electrode of the protecting transistor; and
a first resistor (R0) having a first electrode electrically connected to the source electrode of the protecting transistor;
wherein a power supply is electrically connected to the protecting circuit;
wherein the protecting transistor is configured to hold a voltage applied on the gate electrode of the ESD transistor to ensure the ESD transistor is in an off-state when the power supply supplies a negative voltage to the protecting transistor.

2. The protecting circuit of claim 1, wherein when the power supply is electrically connected to the protecting circuit in correct priority, the ESD transistor and the protecting transistor are turned off.

3. The protecting circuit of claim 1, wherein when the power supply is electrically connected to the protecting circuit in reverse priority, the ESD transistor is turned off and the protecting transistor is turned on.

4. The protecting circuit of claim 1, further comprising:
a second resistor (R1) having a first electrode electrically connected to the capacitor and a second electrode receiving a ground voltage.

5. The protecting circuit of claim 3, wherein the ESD transistor is turned on for a negative ESD stress duration before the ESD transistor is turned off.

6. The protecting circuit of claim 1, further comprising:
a third resistor (Rs) having a first electrode electrically connected to the gate electrode of the ESD transistor, and a second electrode receiving a ground voltage.

7. A protecting circuit comprising:
an electrostatic discharge (ESD) transistor (M0) having a source electrode, a gate electrode, and a drain electrode;
a protecting transistor (M1) having a gate electrode, a drain electrode, and a source electrode electrically connected to the gate electrode of the ESD transistor;
a capacitor (C1) having a first electrode electrically connected to the gate electrode of the protecting transistor, and a second electrode electrically connected to the drain electrode of the protecting transistor;
a first resistor (R0) having a first electrode electrically connected to the source electrode of the protecting transistor; and
a second resistor (R1) having a first electrode electrically connected to the capacitor;
wherein a power supply is electrically connected to the protecting circuit;
wherein the protecting transistor is configured to hold a voltage applied on the gate electrode of the ESD transistor to ensure the ESD transistor is in an off-state when the power supply supplies a negative voltage to the protecting transistor.

8. The protecting circuit of claim 7, wherein when the power supply is electrically connected to the protecting circuit in correct priority, the ESD transistor and the protecting transistor are turned off.

9. The protecting circuit of claim 7, wherein when the power supply is electrically connected to the protecting circuit in reverse priority, the ESD transistor is turned off and the protecting transistor is turned on.

10. The protecting circuit of claim 9, wherein the ESD transistor is turned on for a negative ESD stress duration before the ESD transistor is turned off.

11. The protecting circuit of claim 7, further comprising:
a third resistor (Rs) having a first electrode electrically connected to the gate electrode of the ESD transistor, and a second electrode receiving a ground voltage.

12. A protecting circuit comprising:
an electrostatic discharge (ESD) transistor (M0) having a source electrode, a gate electrode, and a drain electrode; and
an auxiliary circuit electrically connected to the ESD transistor;
wherein when a power supply is electrically connected to the protecting circuit in correct priority, the auxiliary circuit and the ESD transistor are turned on;
wherein when the power supply is electrically connected to the protecting circuit in reverse priority, the auxiliary circuit is turned on so as to turn off the ESD transistor.

13. The protecting circuit of claim 12, wherein the auxiliary circuit includes:
a protecting transistor (M1) having a gate electrode, a drain electrode, and a source electrode electrically connected to the gate electrode of the ESD transistor;
a capacitor (C1) having a first electrode electrically connected to the gate electrode of the protecting transistor, and a second electrode electrically connected to the drain electrode of the protecting transistor;
a first resistor (R0) having a first electrode electrically connected to the source electrode of the protecting transistor; and
a second resistor (R1) having a first electrode electrically connected to the capacitor.

14. The protecting circuit of claim 12, wherein the ESD transistor is turned on for a negative ESD stress duration before the ESD transistor is turned off.

15. The protecting circuit of claim 13, further comprising:
a third resistor (Rs) having a first electrode electrically connected to the gate electrode of the ESD transistor, and a second electrode receiving a ground voltage.
